(19) United States
(12) Patent Application Publication
(10) Pub. No.: US 2019/0372031 A1
(43) Pub. Date: Dec. 5, 2019

(54) COMPOUND AND ORGANIC SOLAR CELL COMPRISING SAME

(71) Applicant: LG CHEM, LTD., Seoul (KR)

(72) Inventors: BOGYU LIM, Daejeon (KR); SONGRIM JANG, Daejeon (KR); DOOWHAN CHOI, Daejeon (KR); Ji HOON KIM, Daejeon (KR)

(21) Appl. No.: 16/472,961

(22) PCT Filed: May 14, 2018
(86) PCT No.: PCT/KR2018/005489

§ 371 Date: Jun. 24, 2019

(30) Foreign Application Priority Data
May 24, 2017 (KR) 10-2017-0064106

(51) Int. Cl. H01L 51/00; C08G 61/12

(52) U.S. Cl. CPC H01L 51/0094; H01L 51/4273; H01L 51/0043; H01L 51/0036; C08G 2261/91; C08G 2261/3243; C08G 2261/124; C08G 2261/18; C08G 2261/228; C08G 2261/144; C08G 2261/1424; C08G 2261/1412; C08G 2261/1428; C08G 2261/149; C08G 2261/3223; C08G 2261/312; C08G 2261/3246; C08G 61/126

(57) ABSTRACT

The present specification provides a compound including a unit represented by Formula 1 and an organic solar cell including the same.

### CROSS-REFERENCE TO RELATED APPLICATIONS

This application is a 35 U.S.C. § 371 national stage application of PCT International Application No. PCT/KR2018/005489, filed May 14, 2018, which claims priority from Korean Patent Application No. 10-2017-0064106, filed May 24, 2017, the contents of which are incorporated herein in their entireties by reference. The above-referenced PCT International Application was published in the Korean language as International Publication No. WO 2018/216936 on Nov. 29, 2018.

### TECHNICAL FIELD

The present specification relates to a compound and an organic solar cell including the same.

### BACKGROUND ART

An organic solar cell is a device which may directly convert solar energy into electric energy by applying a photovoltaic effect. A solar cell may be divided into an inorganic solar cell and an organic solar cell, depending on the materials constituting a thin film. Typical solar cells are made through a p-n junction by doping crystalline silicon (Si), which is an inorganic semiconductor. Electrons and holes generated by absorbing light diffuse to p-n junction points and move to an electrode while being accelerated by the electric field. The power conversion efficiency in this process is defined as the ratio of electric power given to an external circuit and solar power entering the solar cell, and the efficiency have reached approximately 24% when measured under a currently standardized virtual solar irradiation condition. However, since inorganic solar cells in the related art have already shown the limitation in economic feasibility and material demands and supplies, an organic semiconductor solar cell, which is easily processed and inexpensive and has various functionalities, has come into the spotlight as a long-term alternative energy source.

For the solar cell, it is important to increase efficiency so as to output as much electric energy as possible from solar energy. In order to increase the efficiency of the solar cell, it is important to generate as many excitons as possible inside a semiconductor, but it is also important to pull the generated charges to the outside without loss. One of the reasons for the charge loss is the dissipation of generated electrons and holes due to recombination. Various methods have been proposed to deliver generated electrons and holes to an electrode without loss, but additional processes are required in most cases, and accordingly, manufacturing costs may be increased.

### DETAILED DESCRIPTION OF THE INVENTION

### Technical Problem

An object of the present specification is to provide a compound and an organic solar cell including the same.

### Technical Solution

An exemplary embodiment of the present specification provides a compound including a unit represented by the following Formula 1.

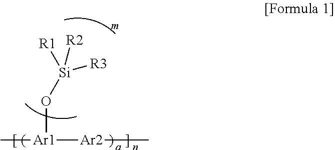

In Formula 1,

Ar1 is a substituted or unsubstituted aryl group; or a substituted or unsubstituted heterocyclic group,

Ar2 is a substituted or unsubstituted alkylene group; a substituted or unsubstituted cycloalkylene group; a substituted or unsubstituted arylene group; or a substituted or unsubstituted divalent heterocyclic group,

R1 to R3 are the same as or different from each other, and are each independently an alkyl group,

a is an integer from 1 to 5,

when a is 2 or more, Ar2's are the same as or different from each other,

n is an integer from 1 to 10,000, and

m is 1 or 2.

Another exemplary embodiment of the present specification provides an organic solar cell including: a first electrode;

a second electrode provided to face the first electrode; and

an organic material layer having one or more layers provided between the first electrode and the second electrode and including a photoactive layer,

in which one or more layers of the organic material layer include the compound.

### Advantageous Effects

The compound of the present specification may be used as a material for an organic material layer of an organic solar cell, and an organic solar cell including the same may exhibit characteristics which are excellent in an increase in open-circuit voltage and short-circuit current and/or an increase in efficiency, and the like.

The compound according to an exemplary embodiment of the present specification has an improved solubility by introducing a bulky alkyl chain into a side chain, and thus may be used in mixture with another material, and has improved crystallinity, and has an economic advantage in terms of time and/or costs during the manufacture of a device.

### BRIEF DESCRIPTION OF DRAWINGS

FIG. 1 is a view illustrating an organic solar cell according to an exemplary embodiment of the present specification.

FIG. 2 is a view illustrating an NMR spectrum of Compound 1-b.

FIG. 3 is a view illustrating an NMR spectrum of Compound 1-c.

FIG. 4 is a view illustrating an NMR spectrum of Compound A-1.

FIG. 5 is a view illustrating an NMR spectrum of Compound 1-e.

FIG. 6 is a view illustrating an MS spectrum of Compound A-2.

FIG. 7 is a view illustrating an NMR spectrum of Compound A-2.

FIG. 8 illustrates a current density according to a voltage with respect to organic solar cells manufactured in exemplary embodiments of the present specification.

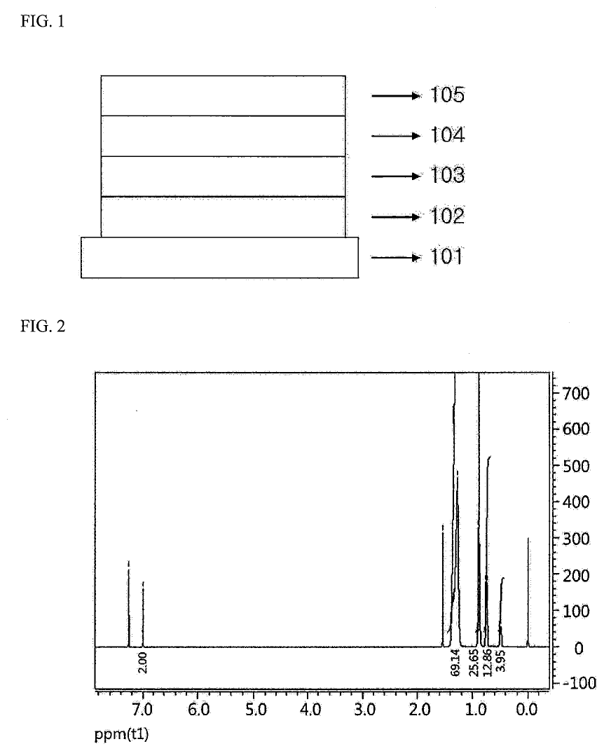

### BEST MODE

Hereinafter, the present specification will be described in detail.

An exemplary embodiment of the present specification provides the compound represented by Formula 1.

The compound according to an exemplary embodiment of the present specification implements high efficiency, and simultaneously has an appropriate solubility, and thus may be used in mixture with another material and has improved crystallinity, and has an economic advantage in terms of time and/or costs during the manufacture of a device.

Further, the compound according to an exemplary embodiment of the present specification has high crystallinity, and thus has an effect in that the charge mobility is improved.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

In the present specification, the “combination” means that multiple identical structures are linked to each other, or different types of structures are linked to each other.

Examples of the substituents in the present specification will be described below, but are not limited thereto.

In the present specification,

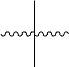

means a moiety bonded to another substituent or a bonding portion.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, the term “substituted or unsubstituted” means being unsubstituted or substituted with one or more substituents selected from the group consisting of deuterium; a halogen group; a nitrile group; a nitro group; a hydroxyl group; a carbonyl group; an ester group; an imide group; an amine group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and a heterocyclic group, or being unsubstituted or substituted with a substituent to which two or more substituents are linked among the substituents exemplified above. For example, “the substituent to which two or more substituents are linked” may be a biphenyl group. That is, the biphenyl group may also be an aryl group, and may be interpreted as a substituent to which two phenyl groups are linked.

In the present specification, the number of carbon atoms of a carbonyl group is not particularly limited, but is preferably 1 to 40. Specifically, the carbonyl group may be a compound having the following structures, but is not limited thereto.

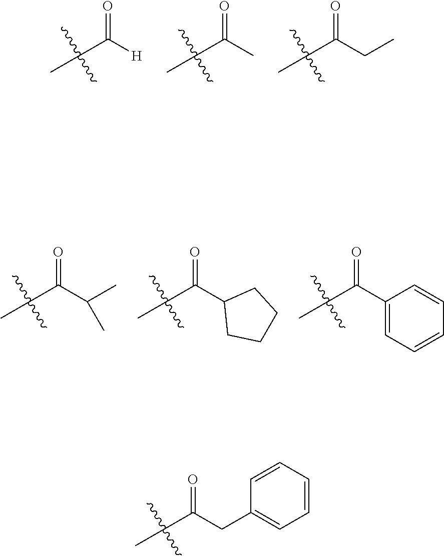

In the present specification, for an ester group, the oxygen of the ester group may be substituted with a straight-chained, branched, or cyclic alkyl group having 1 to 25 carbon atoms, or an aryl group having 6 to 25 carbon atoms. Specifically, the ester group may be a compound having the following structural formulae, but is not limited thereto.

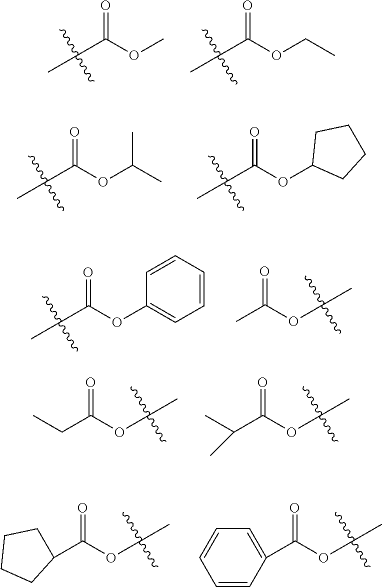

In the present specification, for an amide group, the nitrogen of the amide group may be substituted with hydrogen, a straight-chained, branched, or cyclic alkyl group having 1 to 30 carbon atoms, or an aryl group having 6 to 30 carbon atoms. Specifically, the amide group may be a compound having the following structural formulae, but is not limited thereto.

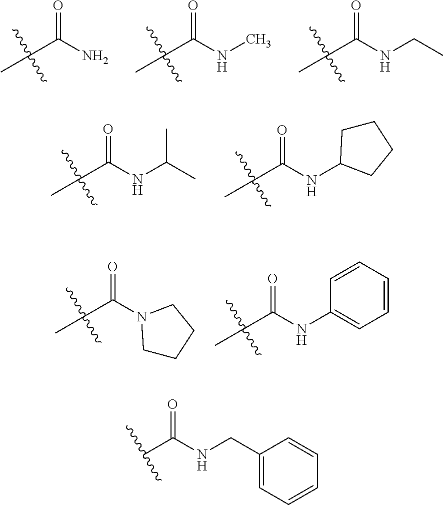

In the present specification, the number of carbon atoms of an imide group is not particularly limited, but is preferably 1 to 25. Specifically, the imide group may be a compound having the following structures, but is not limited thereto.

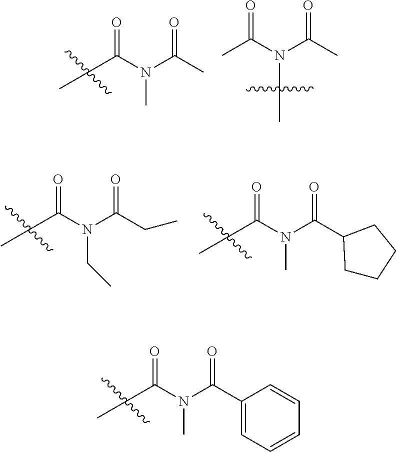

In the present specification, a silyl group may be represented by a formula of —SiRₐR_{b}R_{c}, and Rₐ, R_{b}, and R_{c} may be each hydrogen; a substituted or unsubstituted alkyl group; or a substituted or unsubstituted aryl group. Specific examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but are not limited thereto.

In the present specification, a boron group may be represented by a formula of —BRₐR_{b}, and Rₐ and R_{b} may be each hydrogen; a substituted or unsubstituted alkyl group; or a substituted or unsubstituted aryl group. Specific examples of the boron group include a trimethylboron group, a triethylboron group, a t-butyldimethylboron group, a triphenylboron group, a phenylboron group, and the like, but are not limited thereto.

In the present specification, examples of a halogen group include fluorine, chlorine, bromine or iodine.

In the present specification, the alkyl group may be straight-chained or branched, and the number of carbon atoms thereof is not particularly limited, but is preferably 1 to 40. According to an exemplary embodiment, the number of carbon atoms of the alkyl group is 1 to 20. According to another exemplary embodiment, the number of carbon atoms of the alkyl group is 1 to 10. According to still another exemplary embodiment, the number of carbon atoms of the alkyl group is 1 to 6. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 4-methylhexyl, 5-methylhexyl, and the like, but are not limited thereto.

In the present specification, the alkenyl group may be straight-chained or branched, and the number of carbon atoms thereof is not particularly limited, but is preferably 2 to 40. According to an exemplary embodiment, the number of carbon atoms of the alkenyl group is 2 to 20. According to another exemplary embodiment, the number of carbon atoms of the alkenyl group is 2 to 10. According to still another exemplary embodiment, the number of carbon atoms of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present specification, a cycloalkyl group is not particularly limited, but has preferably 3 to 60 carbon atoms, and according to an exemplary embodiment, the number of carbon atoms of the cycloalkyl group is 3 to 30. According to another exemplary embodiment, the number of carbon atoms of the cycloalkyl group is 3 to 20. According to still another exemplary embodiment, the number of carbon atoms of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present specification, an alkoxy group is not particularly limited, but has preferably 1 to 40 carbon atoms. According to an exemplary embodiment, the number of carbon atoms of the alkoxy group is 1 to 10. According to another exemplary embodiment, the number of carbon atoms of the alkoxy group is 1 to 6. Specific examples of the alkoxy group include a methoxy group, an ethoxy group, a propoxy group, an isobutyloxy group, a sec-butyloxy group, a pentyloxy group, an iso-amyloxy group, a hexyloxy group, and the like, but are not limited thereto.

In the present specification, an amine group may include: an alkylamine group; an aralkylamine group; a heteroarylamine group; and an arylamine group.

In the present specification, the number of carbon atoms of the amine group is not particularly limited, but is preferably 1 to 30. Specific examples of the amine group include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, a phenylnaphthylamine group, a ditolylamine group, a phenyltolylamine group, a triphenylamine group, and the like, but are not limited thereto.

In the present specification, examples of the arylamine group include a substituted or unsubstituted monoarylamine group, a substituted or unsubstituted diarylamine group, or a substituted or unsubstituted triarylamine group. The aryl group in the arylamine group may be a monocyclic aryl group or a polycyclic aryl group. The arylamine group including two or more aryl group may include a monocyclic aryl group, a polycyclic aryl group, or both a monocyclic aryl group and a polycyclic aryl group.

Specific examples of the arylamine group include phenylamine, naphthylamine, biphenylamine, anthracenylamine, 3-methyl-phenylamine, 4-methyl-naphthylamine, 2-methyl-biphenylamine, 9-methyl-anthracenylamine, a diphenylamine group, a phenylnaphthylamine group, a ditolylamine group, a phenyltolylamine group, carbazole, a triphenylamine group, and the like, but are not limited thereto.

In the present specification, examples of an arylphosphine group include a substituted or unsubstituted monoarylphosphine group, a substituted or unsubstituted diarylphosphine group, or a substituted or unsubstituted triarylphosphine group. The aryl group in the arylphosphine group may be a monocyclic aryl group, and may be a polycyclic aryl group. The arylphosphine group including two or more aryl groups may include a monocyclic aryl group, a polycyclic aryl group, or both a monocyclic aryl group and a polycyclic aryl group.

In the present specification, an aryl group is not particularly limited, but has preferably 6 to 60 carbon atoms, and may be a monocyclic aryl group or a polycyclic aryl group. According to an exemplary embodiment, the number of carbon atoms of the aryl group is 6 to 30. According to an exemplary embodiment, the number of carbon atoms of the aryl group is 6 to 20. Examples of the monocyclic aryl group include a phenyl group, a biphenyl group, a terphenyl group, and the like, but are not limited thereto. Examples of the polycyclic aryl group include a naphthyl group, an anthracenyl group, a phenanthryl group, a pyrenyl group, a perylenyl group, a chrysenyl group, a fluorenyl group, a triphenylene group, and the like, but are not limited thereto.

In the present specification, a fluorenyl group may be substituted, and two substituents may be bonded to each other to form a spiro structure.

When the fluorenyl group is substituted, the fluorenyl group may be

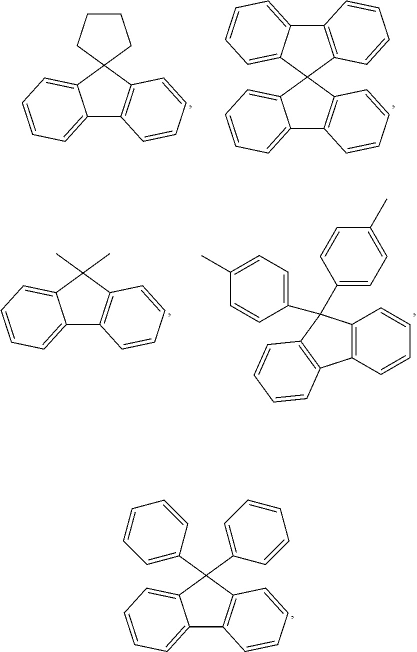

and the like. However, the substituent is not limited thereto.

In the present specification, a heterocyclic group is a heterocyclic group including one or more of N, O, S, Si, and Se as a heteroatom, and the number of carbon atoms thereof is not particularly limited, but is preferably 2 to 60. Examples of the heterocyclic group include a thiophene group, a furan group, a pyrrole group, an imidazole group, a thiazole group, an oxazole group, an oxadiazole group, a triazole group, a pyridyl group, a bipyridyl group, a pyrimidyl group, a triazine group, a triazole group, an acridyl group, a pyridazine group, a pyrazinyl group, a qinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzimidazole group, a benzothiazole group, a benzocarbazole group, a benzothiophene group, a dibenzothiophene group, a benzofuranyl group, a phenanthroline group, a thiazolyl group, an isoxazolyl group, an oxadiazolyl group, a thiadiazolyl group, a phenoxazinyl group, a phenothiazinyl group, a dibenzofuranyl group, and the like, but are not limited thereto. The heterocyclic group may be monocyclic or polycyclic, and includes an aliphatic heterocyclic group and an aromatic heterocyclic group.

In the present specification, examples of the heteroarylamine group include a substituted or unsubstituted monoheteroarylamine group, a substituted or unsubstituted diheteroarylamine group, or a substituted or unsubstituted triheteroarylamine group. The heteroarylamine group including two or more heteroaryl groups may include a monocyclic heteroaryl group, a polycyclic heteroaryl group, or both a monocyclic heteroaryl group and a polycyclic heteroaryl group. For example, the heteroaryl group in the heteroarylamine group may be selected from the above-described examples of the heteroaryl group.

In the present specification, examples of the heteroaryl group in the N-arylheteroarylamine group and the N-alkylheteroarylamine group are the same as the above-described examples of the heteroaryl group.

In the present specification, an aromatic ring group may be monocyclic or polycyclic, and may be selected from the examples of the aryl group.

In the present specification, the above-described description on the aryl group may be applied to an aryl group in an aryloxy group, an arylthioxy group, an arylsulfoxy group, an arylphosphine group, an aralkyl group, an aralkylamine group, an aralkenyl group, an alkylaryl group, an arylamine group, and an arylheteroarylamine group.

In the present specification, the above-described description on the alkyl group may be applied to an alkyl group in an alkylthioxy group, an alkylsulfoxy group, an aralkyl group, an aralkylamine group, an alkylaryl group, and an alkylamine group.

In the present specification, the above-described description on the heterocyclic group may be applied to a heteroaryl group in a heteroaryl group, a heteroarylamine group, and an arylheteroarylamine group, except for an aromatic ring.

In the present specification, the above-described description on the aryl group may be applied to an arylene group except for a divalent arylene group.

In the present specification, an alkylene group means a group having two bonding positions in an alkyl group, that is, a divalent group. The above-described description on the alkyl group may be applied to the alkylene group, except for a divalent group.

In the present specification, the cycloalkylene group means a group having two bonding positions in a cycloalkyl group, that is, a divalent group. The above-described description on the cycloalkyl group may be applied to the cycloalkylene groups, except for a divalent group.

In the present specification, the above-described description on the heterocyclic group may be applied to a divalent heterocyclic group except for a divalent group.

In an exemplary embodiment of the present specification, Formula 1 is represented by the following Formula 2.

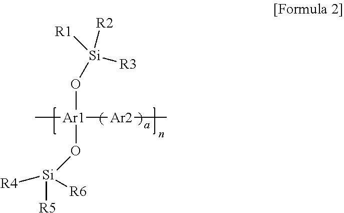

In Formula 2,

Ar1, Ar2, a, and n are the same as those defined in Formula 1, and

R1 to R6 are the same as or different from each other, and are each independently an alkyl group.

In an exemplary embodiment of the present specification, Ar1 is a substituted or unsubstituted trivalent aryl group; a substituted or unsubstituted tetravalent aryl group; a substituted or unsubstituted trivalent heterocyclic group; or a substituted or unsubstituted tetravalent heterocyclic group.

In an exemplary embodiment of the present specification, Ar1 includes any one or a combination of two or more among the following structures.

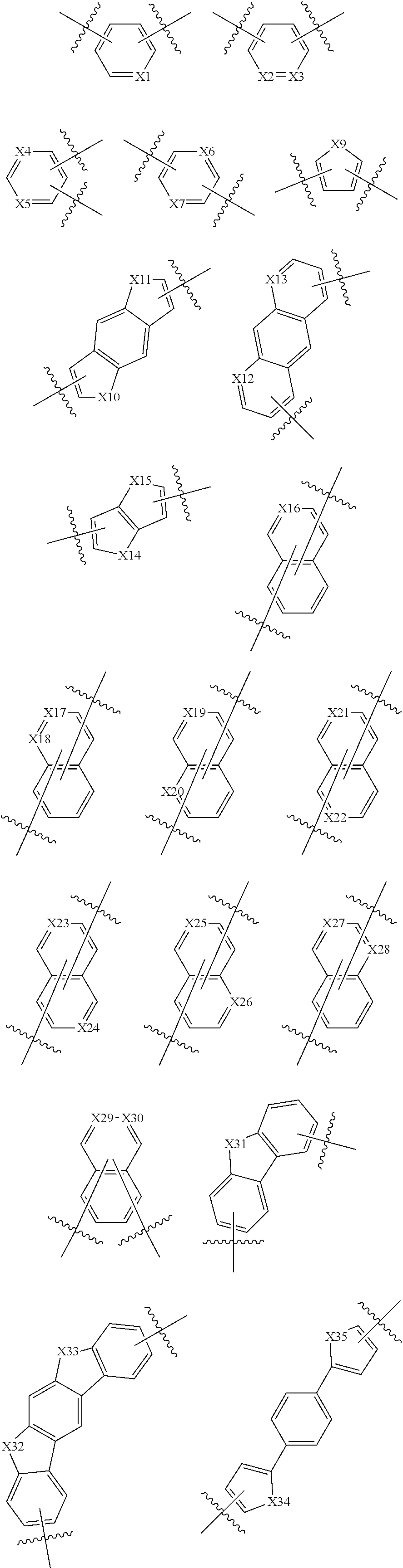

In the structures, X1 to X7, X12, X13, and X16 to X30 are the same as or different from each other, and are each independently N, CR, SiR, P, or GeR,

X9 to X11, X14, X15, and X31 to X35 are the same as or different from each other, and are each independently S, O, Se, Te, NR, CRR′, SiRR′, PR′, or GeRR′,

R and R′ are the same as or different from each other, and are each independently hydrogen; deuterium; a halogen group; a nitrile group; a nitro group; a hydroxyl group; a carbonyl group; an ester group; an imide group; an amide group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted silyl group; a substituted or unsubstituted boron group; a substituted or unsubstituted amine group; a substituted or unsubstituted arylphosphine group; a substituted or unsubstituted phosphine oxide group; a substituted or unsubstituted aryl group; or a substituted or unsubstituted heterocyclic group, and

one or two hydrogen atom(s) in the structural formulae is or are substituted with

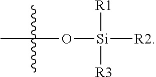

In an exemplary embodiment of the present specification, Ar1 is

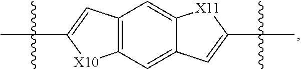

two of the hydrogen atoms in the structure are substituted with

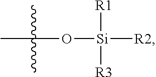

and X10 and X11 are the same as those described above.

In an exemplary embodiment of the present specification, Ar1 is

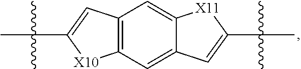

two of the hydrogen atoms in the structure are substituted with

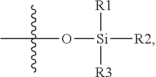

X10 and X11 are S, and R1 to R3 are an alkyl group having 1 to 30 carbon atoms.

In an exemplary embodiment of the present specification, Ar1 is

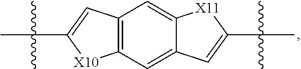

two of the hydrogen atoms in the structure are substituted with

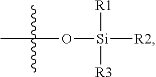

X10 and X11 are S, and R1 to R3 are an alkyl group having 1 to 20 carbon atoms.

In an exemplary embodiment of the present specification, Ar1 is

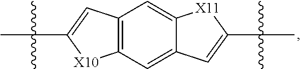

two of the hydrogen atoms in the structure are substituted with

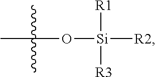

X10 and X11 are S, and R1 to R3 are an alkyl group having 4 to 20 carbon atoms.

In an exemplary embodiment of the present specification, Ar1 is

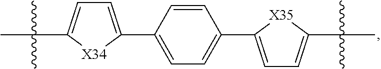

two of the hydrogen atoms in the structure are substituted with

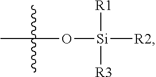

and X34, X35, and R1 to R3 are the same as those described above.

In an exemplary embodiment of the present specification, Ar1 is

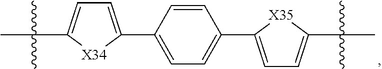

two of the hydrogen atoms in the structure are substituted with

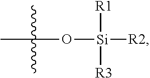

X34 and X35 are S, and R1 to R3 are an alkyl group having 1 to 30 carbon atoms.

In an exemplary embodiment of the present specification, Ar1 is

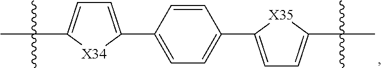

two of the hydrogen atoms in the structure are substituted with

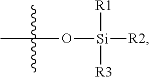

X34 and X35 are S, and R1 to R3 are an alkyl group having 1 to 20 carbon atoms.

In an exemplary embodiment of the present specification, Ar1 is

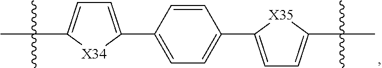

two of the hydrogen atoms in the structure are substituted with

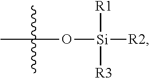

X34 and X35 are S, and R1 to R3 are an alkyl group having 4 to 20 carbon atoms.

In an exemplary embodiment of the present specification, a structure in which two of hydrogen atoms of

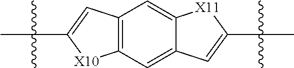

are substituted with

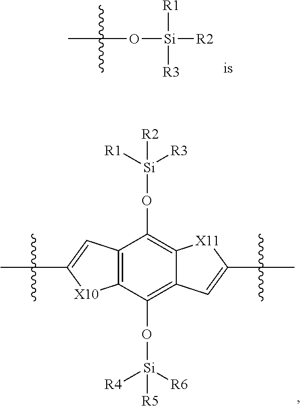

and the definitions of R4 to R6 are the same as the definitions of R1 to R3.

In an exemplary embodiment of the present specification, a structure in which two of hydrogen atoms of

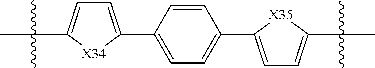

are substituted with

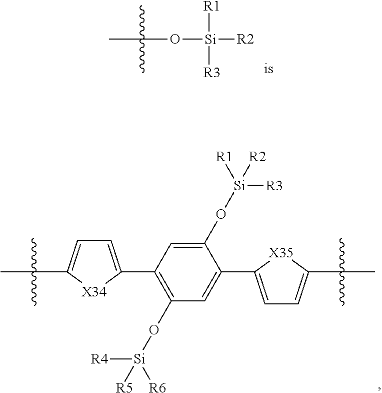

and the definitions of R4 to R6 are the same as the definitions of R1 to R3.

In an exemplary embodiment of the present specification, Formula 1 is represented by the following Formula 1-1 or 1-2.

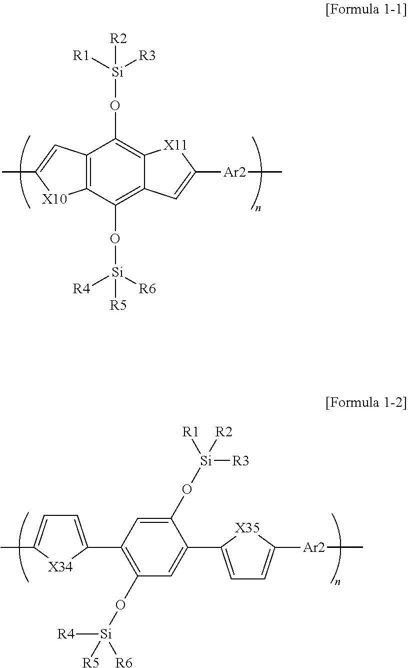

In Formula 1-1 or 1-2,

Ar2, R1 to R3, and n are the same as those defined in Formula 1,

X10, X11, X34, and X35 are the same as or different from each other, and are each independently S, O, Se, Te, NR, CRR′, SiRR′, PR′, or GeRR′,

R4 to R6 are the same as or different from each other, and are each independently an alkyl group, and

R and R′ are the same as or different from each other, and are each independently hydrogen; deuterium; a halogen group; a nitrile group; a nitro group; a hydroxyl group; a carbonyl group; an ester group; an imide group; an amide group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted silyl group; a substituted or unsubstituted boron group; a substituted or unsubstituted amine group; a substituted or unsubstituted arylphosphine group; a substituted or unsubstituted phosphine oxide group; a substituted or unsubstituted aryl group; or a substituted or unsubstituted heterocyclic group.

In an exemplary embodiment of the present specification, Ar2 includes any one or a combination of two or more among the following structures.

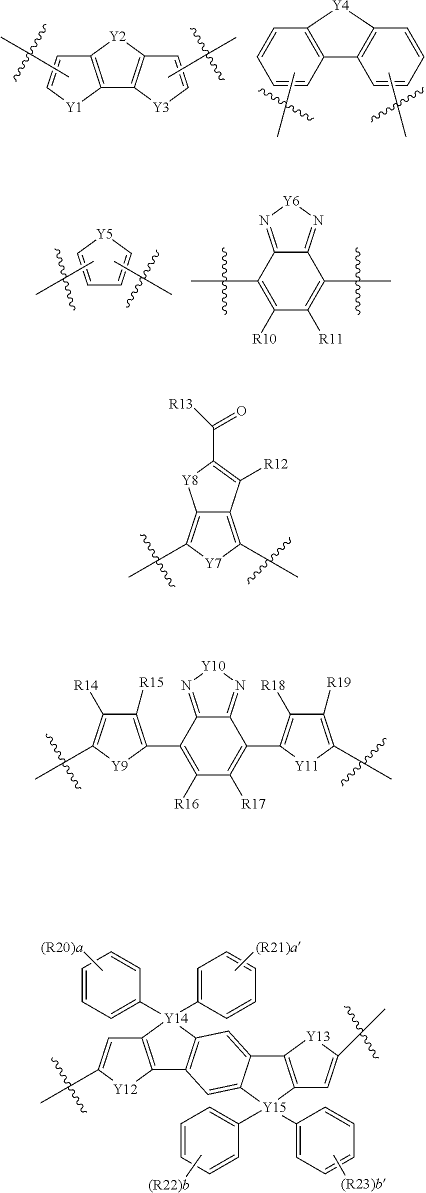

In the structures,

a, a′, b, and b′ are the same as or different from each other, and are each an integer from 0 to 5,

when a, a′, b, and b′ are 2 or more, the substituents in the parenthesis are the same as or different from each other,

Y1 to Y13 are the same as or different from each other, and are each independently S, O, Se, Te, NR, CRR′, SiRR′, PR′, or GeRR′,

Y14 and Y15 are the same as or different from each other, and are each independently C, Si, or Ge, and

R10 to R23 are the same as or different from each other, and are each independently hydrogen; deuterium; a halogen group; a nitrile group; a nitro group; a hydroxyl group; a carbonyl group; an ester group; an imide group; an amide group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted silyl group; a substituted or unsubstituted boron group; a substituted or unsubstituted amine group; a substituted or unsubstituted arylphosphine group; a substituted or unsubstituted phosphine oxide group; a substituted or unsubstituted aryl group; or a substituted or unsubstituted heterocyclic group.

In an exemplary embodiment of the present specification, Ar2 is

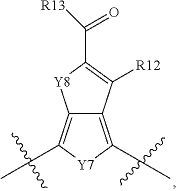

and Y7, Y8, R12, and R13 are the same as those described above.

In an exemplary embodiment of the present specification, Ar2 is

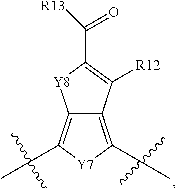

Y7 and Y8 are S, R12 is a halogen group, and R13 is a substituted or unsubstituted alkyl group.

In an exemplary embodiment of the present specification, Ar2 is

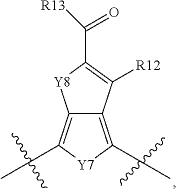

Y7 and Y8 are S, R12 is a halogen group, and R13 is a straight-chained or branched alkyl group.

In an exemplary embodiment of the present specification, Ar2 is

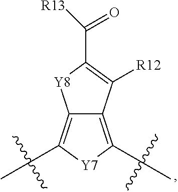

Y7 and Y8 are S, R12 is fluorine, and R13 is a straight-chained or branched alkyl group having 1 to 30 carbon atoms.

In an exemplary embodiment of the present specification, Ar2 is

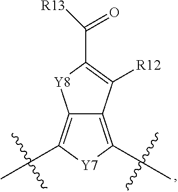

Y7 and Y8 are S, R12 is fluorine, and R13 is a straight-chained or branched alkyl group having 1 to 20 carbon atoms.

In an exemplary embodiment of the present specification, Ar2 is

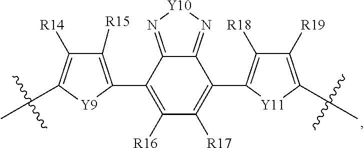

and Y9 to Y11 and R14 to R19 are the same as those described above.

In an exemplary embodiment of the present specification, Ar2 is

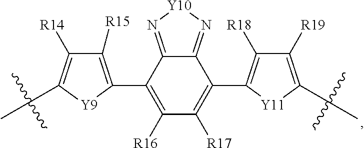

Y9 to Y11 are S, R14, R15, R18, and R19 are hydrogen, and R16 and R17 are the same as or different from each other, and are each independently a halogen group; or a substituted or unsubstituted alkoxy group.

In an exemplary embodiment of the present specification, Ar2 is

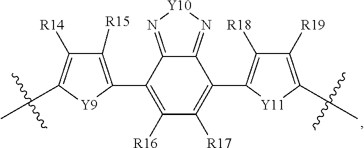

Y9 to Y11 are S, R14, R15, R18, and R19 are hydrogen, and R16 and R17 are the same as or different from each other, and are each independently fluorine; or an alkoxy group substituted with an alkyl group.

In an exemplary embodiment of the present specification, Ar2 is

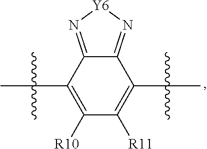

and Y6, R10, and R11 are the same as those described above.

In an exemplary embodiment of the present specification, Ar2 is

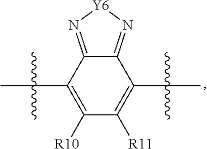

Y6 is S, and R10 and R11 are the same as or different from each other, and are each independently a halogen group; or a substituted or unsubstituted alkoxy group.

In an exemplary embodiment of the present specification, Ar2 is

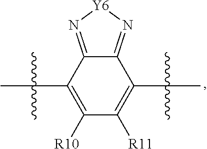

Y6 is S, and R10 and R11 are the same as or different from each other, and are each independently fluorine; or an alkoxy group substituted with an alkyl group.

In an exemplary embodiment of the present specification, Formula 1 is represented by any one of the following Formulae 1-11 to 1-16.

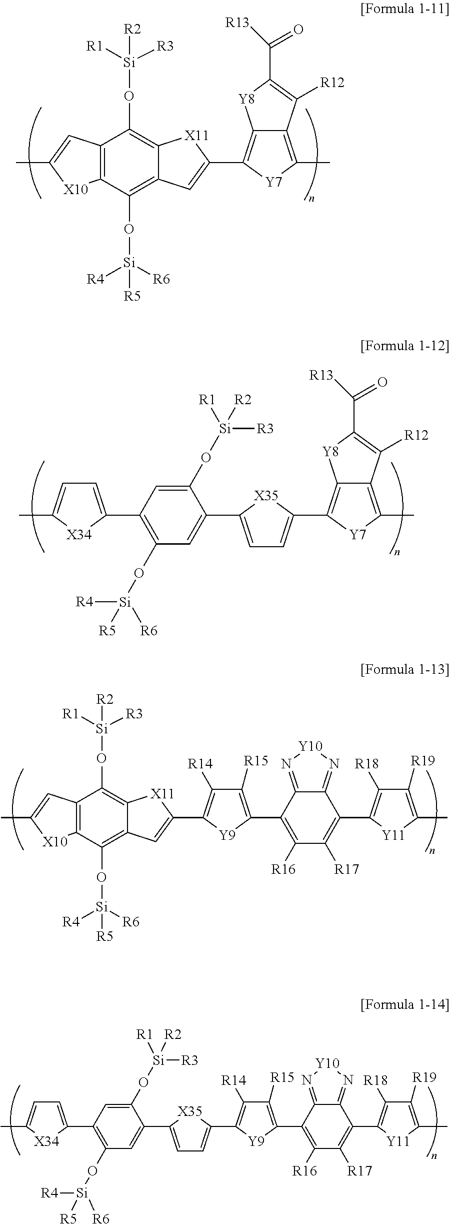

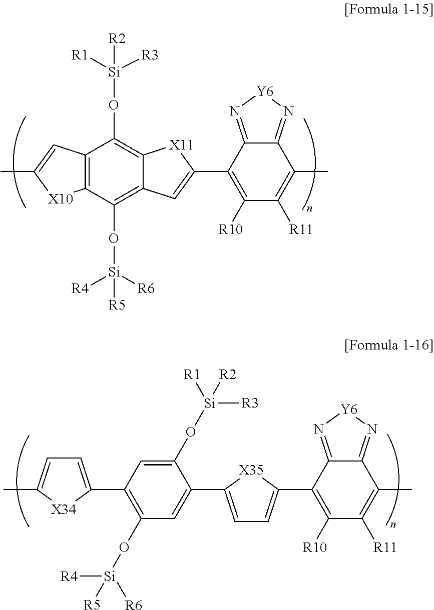

In Formulae 1-11 to 1-16,

R1 to R3 and n are the same as those defined in Formula 1,

X10, X11, X34, X35, and Y6 to Y11 are the same as or different from each other, and are each independently S, O, Se, Te, NR, CRR′, SiRR′, PR′, or GeRR′,

R4 to R6 are the same as or different from each other, and are each independently an alkyl group, and

R10 to R19, R, and R′ are the same as or different from each other, and are each independently hydrogen; deuterium; a halogen group; a nitrile group; a nitro group; a hydroxyl group; a carbonyl group; an ester group; an imide group; an amide group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted silyl group; a substituted or unsubstituted boron group; a substituted or unsubstituted amine group; a substituted or unsubstituted arylphosphine group; a substituted or unsubstituted phosphine oxide group; a substituted or unsubstituted aryl group; or a substituted or unsubstituted heterocyclic group.

In an exemplary embodiment of the present specification, X10, X11, X34, and X35 are the same as or different from each other, and are each independently S, O, or NR, and R is the same as that described above.

In an exemplary embodiment of the present specification, X10, X11, X34, and X35 are S.

In an exemplary embodiment of the present specification, R1 to R6 are the same as or different from each other, and are each independently an alkyl group having 1 to 30 carbon atoms.

In an exemplary embodiment of the present specification, R1 to R6 are the same as or different from each other, and are each independently an alkyl group having 1 to 20 carbon atoms.

In an exemplary embodiment of the present specification, R1 to R6 are the same as or different from each other, and are each independently an alkyl group having 4 to 20 carbon atoms.

In an exemplary embodiment of the present specification, Y6 to Y11 are the same as or different from each other, and are each independently S, O or NR, and R is the same as that described above.

In an exemplary embodiment of the present specification, Y6 to Y11 are S.

In an exemplary embodiment of the present specification, R13 is a substituted or unsubstituted alkyl group.

In an exemplary embodiment of the present specification, R13 is a straight-chained or branched alkyl group.

In an exemplary embodiment of the present specification, R13 is a straight-chained or branched alkyl group having 1 to 30 carbon atoms.

In an exemplary embodiment of the present specification, R13 is a straight-chained or branched alkyl group having 1 to 20 carbon atoms.

In an exemplary embodiment of the present specification, R12 is a halogen group.

In an exemplary embodiment of the present specification, R12 is fluorine.

In an exemplary embodiment of the present specification, R10, R11, and R14 to R19 are the same as or different from each other, and are each independently hydrogen; a halogen group; a substituted or unsubstituted alkoxy group; a substituted or unsubstituted alkyl group; a substituted or unsubstituted aryl group; or a substituted or unsubstituted heterocyclic group.

In an exemplary embodiment of the present specification, R10, R11, and R14 to R19 are the same as or different from each other, and are each independently hydrogen; a halogen group; or a substituted or unsubstituted alkoxy group.

In an exemplary embodiment of the present specification, R14, R15, R18, and R19 are hydrogen.

In an exemplary embodiment of the present specification, R10, R11, R16, and R17 are the same as or different from each other, and are each independently a halogen group; or a substituted or unsubstituted alkoxy group.

In an exemplary embodiment of the present specification, R10, R11, R16, and R17 are the same as or different from each other, and are each independently a halogen group; or an alkoxy group unsubstituted or substituted with an alkyl group.

In an exemplary embodiment of the present specification, R10, R11, R16, and R17 are the same as or different from each other, and are each independently fluorine; or an alkoxy group substituted with an alkyl group having 1 to 30 carbon atoms.

In an exemplary embodiment of the present specification, R10, R11, R16, and R17 are the same as or different from each other, and are each independently fluorine; or an alkoxy group substituted with an alkyl group having 1 to 20 carbon atoms.

In an exemplary embodiment of the present specification, an end group of the compound is thiophene.

An exemplary embodiment of the present specification provides an organic solar cell including: a first electrode;

a second electrode provided to face the first electrode; and

an organic material layer having one or more layers provided between the first electrode and the second electrode and including a photoactive layer,

in which one or more layers of the organic material layer include the compound.

In an exemplary embodiment of the present specification, the organic solar cell may further include an additional organic material layer. The organic solar cell may reduce the number of organic material layers by using an organic material which simultaneously has various functions.

In an exemplary embodiment of the present specification, the organic solar cell includes a first electrode, a photoactive layer, and a second electrode. The organic solar cell may further include a substrate, a hole transport layer, and/or an electron transport layer.

In an exemplary embodiment of the present specification, the photoactive layer includes the compound.

In an exemplary embodiment of the present specification, the organic material layer includes a hole transport layer, a hole injection layer, or a layer which simultaneously transports and injects holes, and the hole transport layer, the hole injection layer, or the layer which simultaneously transports and injects holes includes the compound.

In another exemplary embodiment, the organic material layer includes an electron injection layer, an electron transport layer, or a layer which simultaneously injects and transports electrons, and the electron injection layer, the electron transport layer, or the layer which simultaneously injects and transports electrons includes the compound.

In an exemplary embodiment of the present specification, the organic solar cell further includes one or two or more organic material layers selected from the group consisting of a hole injection layer, a hole transport layer, a hole blocking layer, a charge generation layer, an electron blocking layer, an electron injection layer, and an electron transport layer.

In an exemplary embodiment of the present specification, in the organic solar cell, a cathode, a photoactive layer, and an anode may be arranged in this order, and an anode, a photoactive layer, and a cathode may be arranged in this order, but the arrangement order is not limited thereto.

In another exemplary embodiment, in the organic solar cell, an anode, a hole transport layer, a photoactive layer, an electron transport layer, and a cathode may also be arranged in this order, and a cathode, an electron transport layer, a photoactive layer, a hole transport layer, and an anode may also be arranged in this order, but the arrangement order is not limited thereto.

In an exemplary embodiment of the present specification, the photoactive layer includes an electron donor and an electron acceptor, and the electron donor includes the compound.

In an exemplary embodiment of the present specification, a material for the electron acceptor may be selected from the group consisting of fullerene, fullerene derivatives, bathocuproine, semi-conducting elements, semi-conducting compounds, and combinations thereof. Specifically, the material for the electron acceptor may be phenyl C₆₀-butyric acid methyl ester (PC₆₀BM), phenyl C₆₁-butyric acid methyl ester (PC₆₁BM), or phenyl C₇₁-butyric acid methyl ester (PC₇₁BM).

In an exemplary embodiment of the present specification, the electron donor and the electron acceptor constitute a bulk heterojunction (BHJ). A material for the electron donor and a material for the electron acceptor may be mixed at a ratio (w/w) of 1:10 to 10:1. Specifically, the material for the electron donor and the material for the electron acceptor may be mixed at a ratio (w/w) of 1:1 to 1:10, and more specifically, the material for the electron donor and the material for the electron acceptor may be mixed at a ratio (w/w) of 1:1 to 1:5. If necessary, the material for the electron donor and the material for the electron acceptor may be mixed at a ratio (w/w) of 1:1 to 1:3.

In an exemplary embodiment of the present specification, the photoactive layer has a bilayer thin film structure including an n-type organic material layer and a p-type organic material layer, and the p-type organic material layer includes the compound.

In the present specification, the substrate may be a glass substrate or a transparent plastic substrate having excellent transparency, surface smoothness, ease of handling, and waterproofing properties, but is not limited thereto, and the substrate is not limited as long as the substrate is typically used in the organic solar cell. Specific examples thereof include glass or polyethylene terephthalate (PET), polyethylene naphthalate (PEN), polypropylene (PP), polyimide (PI), triacetyl cellulose (TAC), and the like, but are not limited thereto.

The first electrode may be a material which is transparent and has excellent conductivity, but is not limited thereto. Examples thereof include: a metal such as vanadium, chromium, copper, zinc, and gold, or an alloy thereof; a metal oxide such as zinc oxide, indium oxide, indium tin oxide (ITO), and indium zinc oxide (IZO); a combination of a metal and an oxide, such as ZnO:Al or SnO₂:Sb; a conductive polymer, such as poly(3-methylthiophene), poly[3,4-(ethylene-1,2-dioxythiophene] (PEDOT), polypyrrole, and polyaniline; and the like, but are not limited thereto.

A method of forming the first electrode is not particularly limited, but the first electrode may be formed, for example, by being applied onto one surface of a substrate using a method such as sputtering, e-beam, thermal deposition, spin coating, screen printing, inkjet printing, doctor blade, or gravure printing, or by being coated in the form of a film.

When the first electrode is formed on a substrate, the first electrode may be subjected to processes of cleaning, removing moisture, and hydrophilic modification.

For example, a patterned ITO substrate is sequentially cleaned with a cleaning agent, acetone, and isopropyl alcohol (IPA), and then dried on a hot plate at 100° C. to 150° C. for 1 to 30 minutes, preferably at 120° C. for 10 minutes in order to remove moisture, and when the substrate is completely cleaned, the surface of the substrate is hydrophilically modified.

Through the surface modification as described above, the junction surface potential may be maintained at a level suitable for a surface potential of a photoactive layer. Further, during the modification, a polymer thin film may be easily formed on the first electrode, and the quality of the thin film may also be improved.

Examples of a pre-treatment technology for the first electrode include a) a surface oxidation method using a parallel flat plate-type discharge, b) a method of oxidizing the surface through ozone produced by using UV rays in a vacuum state, c) an oxidation method using oxygen radicals produced by plasma, and the like.

One of the methods may be selected according to the state of the first electrode or the substrate. However, although any method is used, it is preferred to commonly prevent oxygen from being separated from the surface of the first electrode or the substrate, and maximally inhibit moisture and organic materials from remaining. In this case, it is possible to maximize a substantial effect of the pre-treatment.

As a specific example, it is possible to use a method of oxidizing the surface through ozone produced by using UV. In this case, a patterned ITO substrate after being ultrasonically cleaned is baked on a hot plate and dried well, and then introduced into a chamber, and the patterned ITO substrate may be cleaned by ozone generated by allowing an oxygen gas to react with UV light by operating a UV lamp.

However, the surface modification method of the patterned ITO substrate in the present specification need not be particularly limited, and any method may be used as long as the method is a method of oxidizing a substrate.

The second electrode may be a metal having a low work function, but is not limited thereto. Specific examples thereof include: a metal such as magnesium, calcium, sodium, potassium, titanium, indium, yttrium, lithium, gadolinium, aluminum, silver, tin, and lead, or an alloy thereof; and a multi-layer structured material, such as LiF/Al, LiO₂/Al, LiF/Fe, Al:Li, Al:BaF₂, and Al:BaF₂:Ba, but are not limited thereto.

The second electrode may be deposited and formed in a thermal evaporator showing a vacuum degree of 5×10⁻⁷ torr or less, but the forming method is not limited to this method.

A material for the hole transport layer and/or a material for the electron transport layer serve to efficiently transfer electrons and holes separated from a photoactive layer to an electrode, and the materials are not particularly limited.

The material for the hole transport layer may be poly(3,4-ethylenedioxythiophene) doped with poly(styrenesulfonic acid) (PEDOT:PSS) and molybdenum oxide (MoOₓ); vanadium oxide (V₂O₅); nickel oxide (NiO); tungsten oxide (WOₓ); and the like, but is not limited thereto.

The material for the electron transport layer may be electron-extracting metal oxides, and specific examples thereof include: metal complexes of 8-hydroxyquinoline; complexes including Alq₃; metal complexes including Liq; LiF; Ca; titanium oxide (TiOₓ); zinc oxide (ZnO); cesium carbonate (Cs₂CO₃); and the like, but are not limited thereto.

The photoactive layer may be formed by dissolving a photoactive material such as an electron donor and/or an electron acceptor in an organic solvent, and then applying the solution by a method such as spin coating, dip coating, screen printing, spray coating, doctor blade, and brush painting, but the forming method is not limited thereto.

A preparation method of the compound and the manufacture of an organic solar cell including the same will be described in detail in the following Preparation Examples and Examples. However, the following Examples are provided for exemplifying the present specification, and the scope of the present specification is not limited thereby.

### Preparation Example 1. Preparation of Compound A-1

(1) Preparation of Compound 1-b

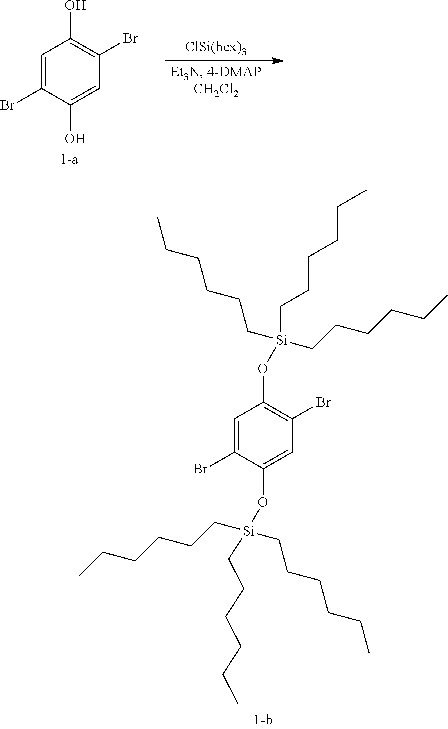 [SMILES: Oc1cc(Br)c(O)cc1Br ; CCCCCC[Si](CCCCCC)(CCCCCC)Oc1cc(Br)c(O[Si](CCCCCC)(CCCCCC)CCCCCC)cc1Br]

Compound 1-a (2 g, 7.47 mmol) and 4-dimethylaminopyridine (4-DMAP) (0.36 g, 2.92 mmol) were dissolved in 30 mL of dichloromethane, and then triethylamine (Et₃N)(3 mL, 21.51 mmol) and trihexylchlorosilane (ClSi(hex)₃) (7.46 mL, 20.37 mmol) were added thereto at 0° C., and the resulting mixture was stirred at room temperature for 12 hours. After the reaction, a reactant was added to 100 mL of water, an extraction was performed with dichloromethane (CH₂Cl₂), the remaining water was removed over magnesium sulfate (MgSO₄), and then the solvent was removed under reduced pressure. The remaining product was purified with silica column (eluent: hexane) to obtain Compound 1-b (yield; 94%).

FIG. 2 is a view illustrating an NMR spectrum of Compound 1-b.

(2) Preparation of Compound 1-c

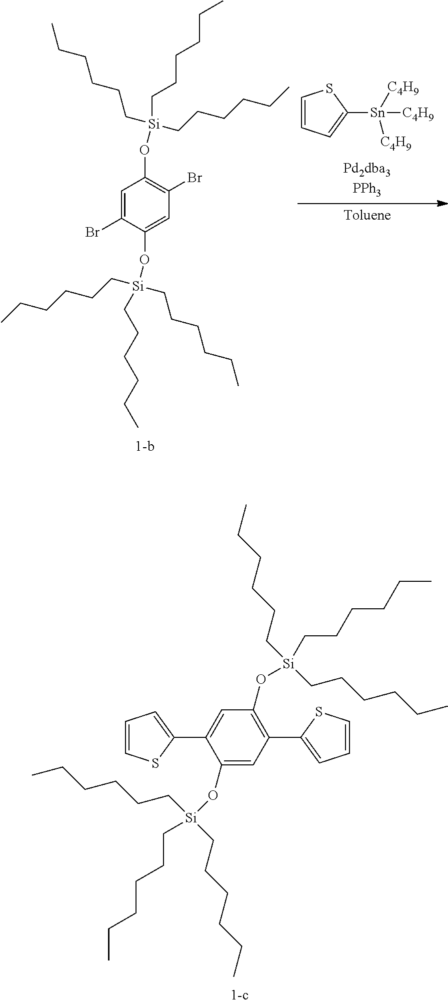

Compound 1-b (5 g, 6 mmol) and tributyltin-thiophene (9.33 g, 25 mmol) were dissolved in 70 mL of toluene and a tris(dibenzylideneacetone)dipalladium(0) (Pd₂dba₃) catalyst (0.458 g, 0.05 mmol) and a triphenylphosphine (PPh₃) ligand (0.52 g, 2 mmol) were added thereto, and the resulting mixture was stirred at 110° C. for 48 hours. After the reaction, an extraction was performed with dichloromethane, the remaining water was removed over magnesium sulfate (MgSO₄), and then the solvent was removed under reduced pressure. The remaining product was purified with silica column (eluent: hexane) to obtain Compound 1-c (yield; 59%).

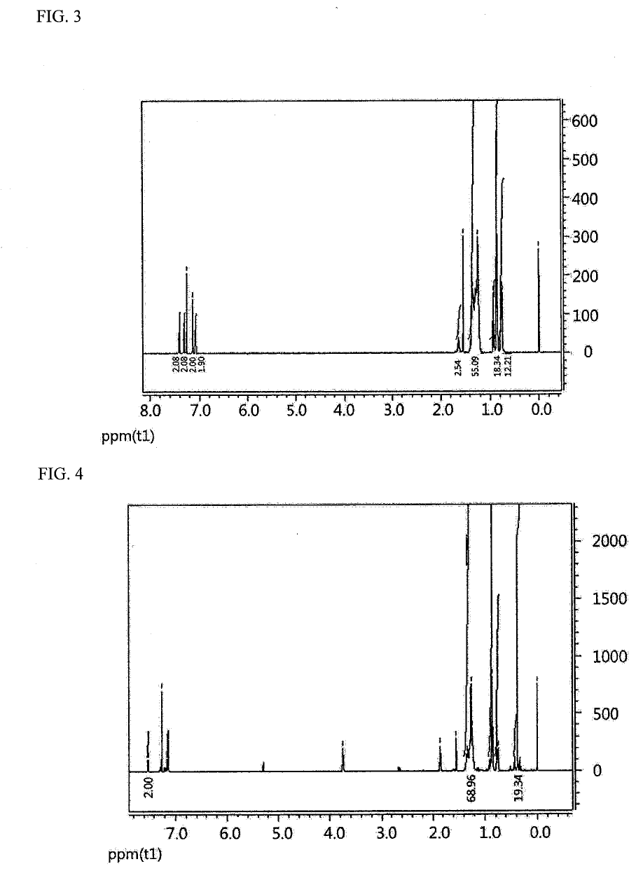

FIG. 3 is a view illustrating an NMR spectrum of Compound 1-c.

(3) Preparation of Compound A-1

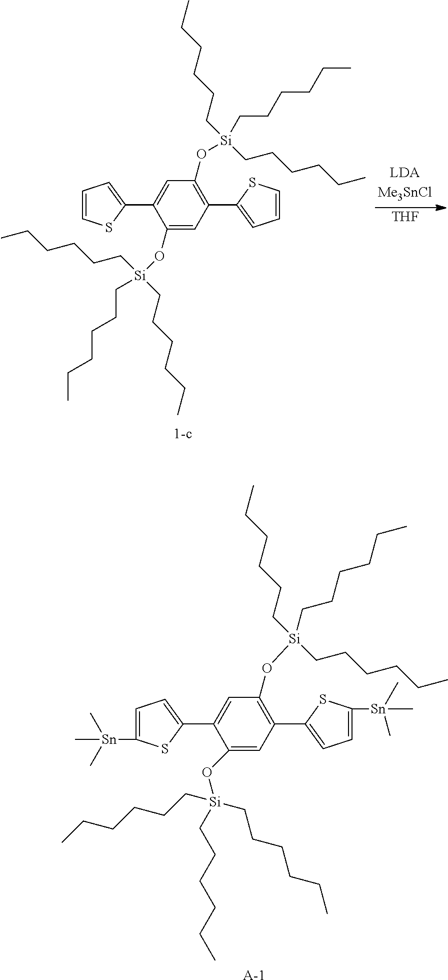

After Compound 1-c (2.7 g, 3.18 mmol) was dissolved in 40 mL of tetrahydrofuran (THF), 2 M lithium diisopropylamide (LDA) (8.75 mL, 17.5 mmol) was slowly injected thereinto at −78° C., and then the resulting mixture was stirred at −78° C. for 2 hours. Trimethyltin chloride (Me₃SnCl) (18 mL, 18 mmol) was added thereto at the same temperature, and the resulting mixture was slowly warmed to room temperature, and then was allowed to react at room temperature for 3 hours. After the reaction, an extraction was performed with dichloromethane, the remaining water was removed over magnesium sulfate (MgSO₄), and then the solvent was removed under reduced pressure, thereby obtaining Compound A-1 (yield 78%).

FIG. 4 is a view illustrating an NMR spectrum of Compound A-1.

### Preparation Example 2. Preparation of Compound A-2

(1) Preparation of Compound 1-e

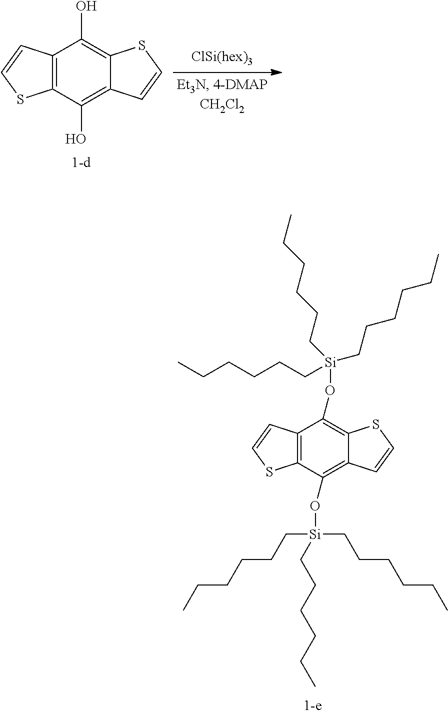 [SMILES: Oc1c2ccsc2c(O)c2ccsc12 ; CCCCCC[Si](CCCCCC)(CCCCCC)Oc1c2ccsc2c(O[Si](CCCCCC)(CCCCCC)CCCCCC)c2ccsc12]

Compound 1-d (1.6 g, 7.47 mmol) and 4-dimethylaminopyridine (4-DMAP) (0.35 g, 2.92 mmol) were dissolved in a solution in which 30 mL of dichloromethane and 5 mL of dimethylformamide-OH (DMF-OH) are mixed, and then triethylamine (Et₃N)(10.2 mmol) and trihexylchlorosilane (ClSi(hex)₃) (7.46 mL, 20.4 mmol) were added thereto at 0° C., and the resulting mixture was stirred at room temperature for 12 hours. After the reaction, a reactant was added to 100 mL of water, an extraction was performed with dichloromethane (CH₂Cl₂), and the remaining product was purified through column chromatography, thereby obtaining Compound 1-e (yield: 19%).

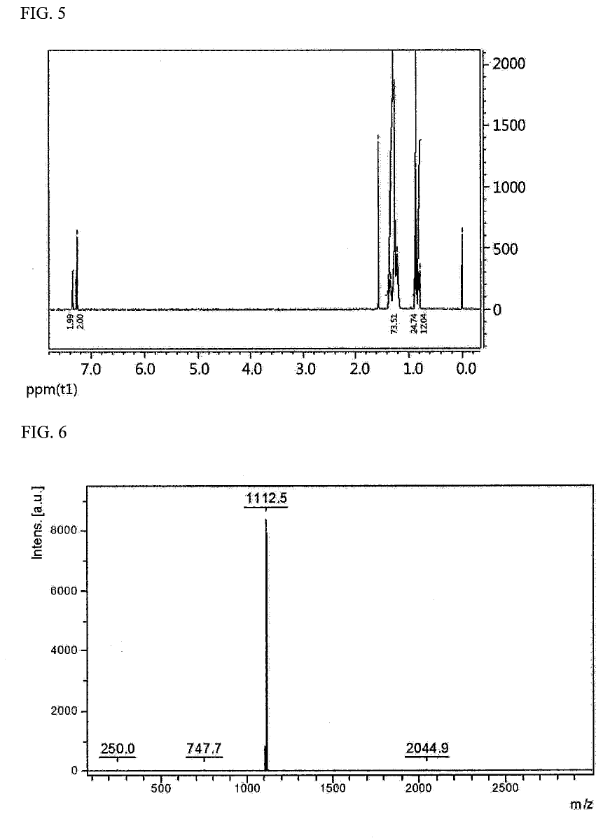

FIG. 5 is a view illustrating an NMR spectrum of Compound 1-e.

(2) Preparation of Compound A-2

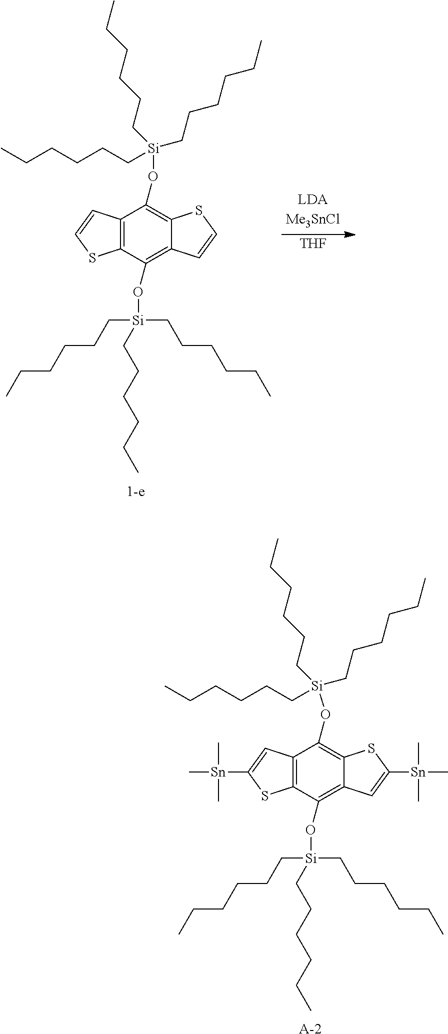

After Compound 1-e (1 g, 1.41 mmol) was dissolved in 30 mL of tetrahydrofuran (THF), 2 M lithium diisopropylamide (LDA) (3.9 mL, 7.8 mmol) was slowly injected thereinto at −78° C., and then the resulting mixture was stirred at −78° C. for 2 hours. Trimethyltin chloride (Me₃SnCl) (8.55 mL, 8.5 mmol) was added thereto at the same temperature, and the resulting mixture was slowly warmed to room temperature, and then stirred at room temperature overnight. After the reaction, an extraction was performed with dichloromethane, the remaining water was removed over magnesium sulfate (MgSO₄), and then the solvent was removed under reduced pressure, thereby obtaining Compound A-2 (yield 76%).

FIG. 6 is a view illustrating an MS spectrum of Compound A-2.

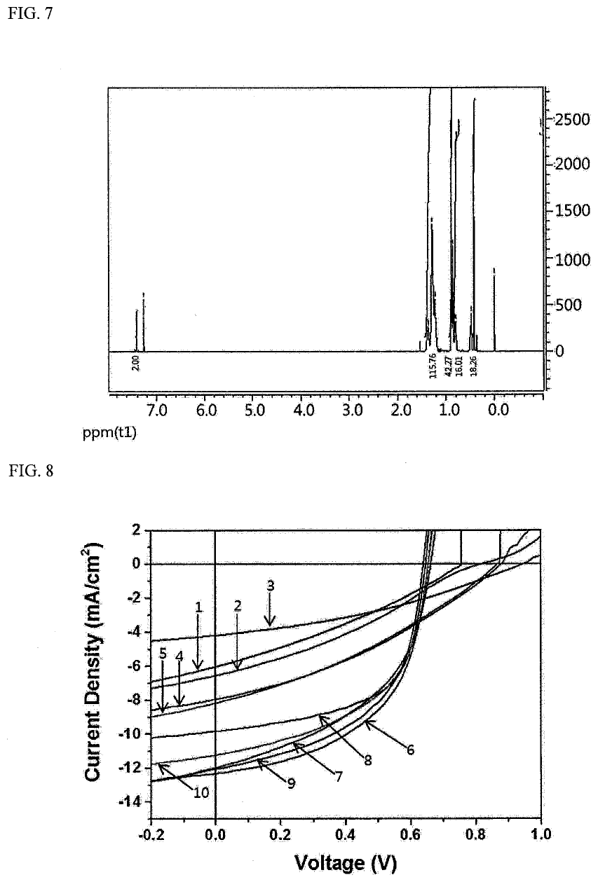

FIG. 7 is a view illustrating an NMR spectrum of Compound A-2.

### Preparation Example 3. Preparation of Compound 1

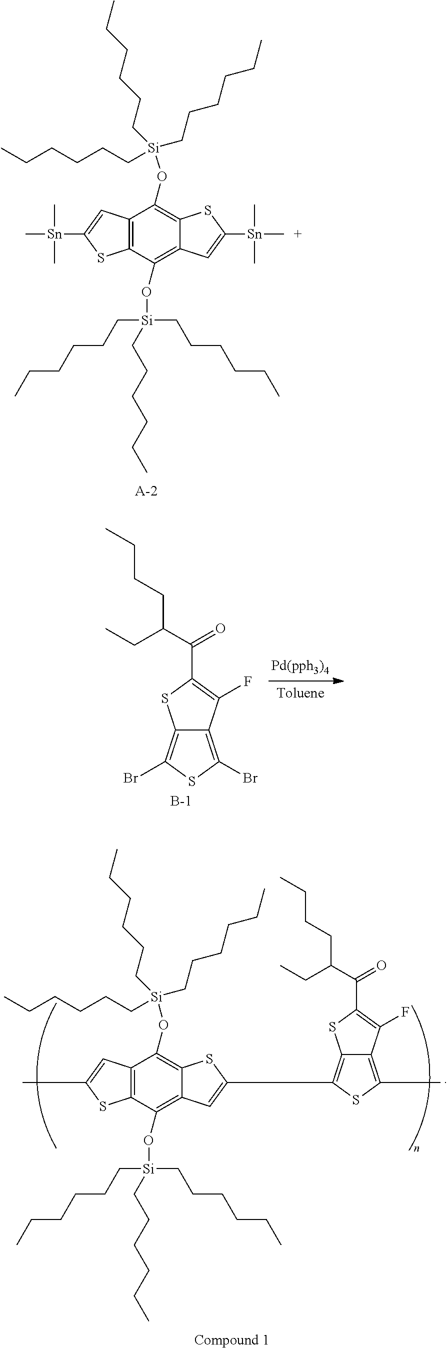

5 mL of toluene, Compound A-2 (0.3 mmol), Compound B-1 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.14 g of Compound 1 (yield: 43.5%).

### Preparation Example 4. Preparation of Compound 2

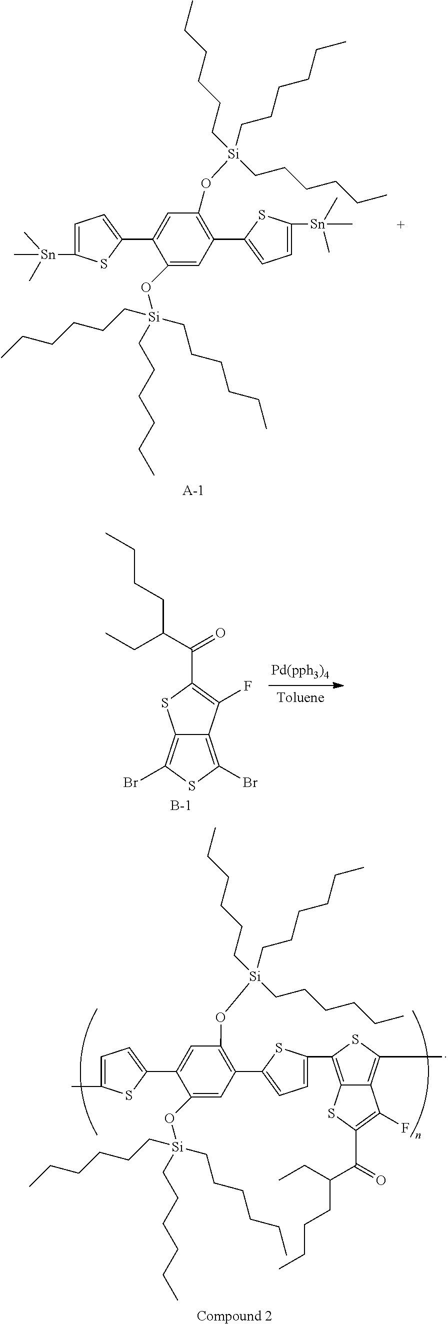

5 mL of toluene, Compound A-1 (0.3 mmol), Compound B-1 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.21 g of Compound 2 (yield: 62.3%).

### Preparation Example 5. Preparation of Compound 3

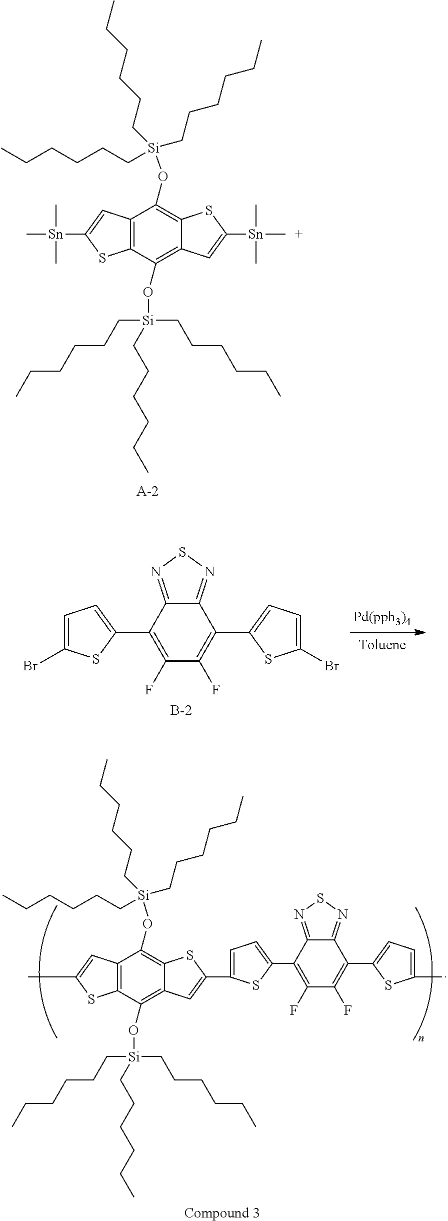

5 mL of toluene, Compound A-2 (0.3 mmol), Compound B-2 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.25 g of Compound 3 (yield: 75.1%).

### Preparation Example 6. Preparation of Compound 4

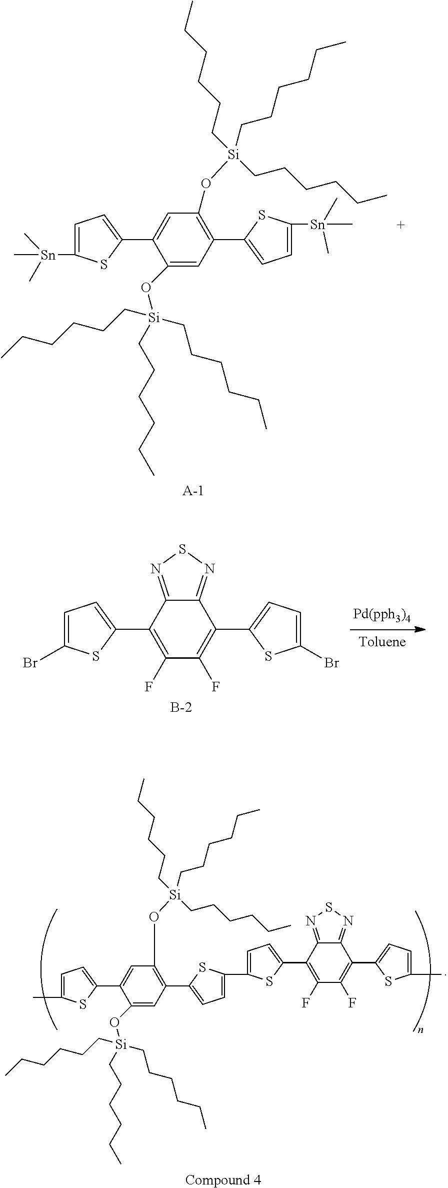

5 mL of toluene, Compound A-1 (0.3 mmol), Compound B-2 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.19 g of Compound 4 (yield: 53.8%).

### Preparation Example 7. Preparation of Compound 5

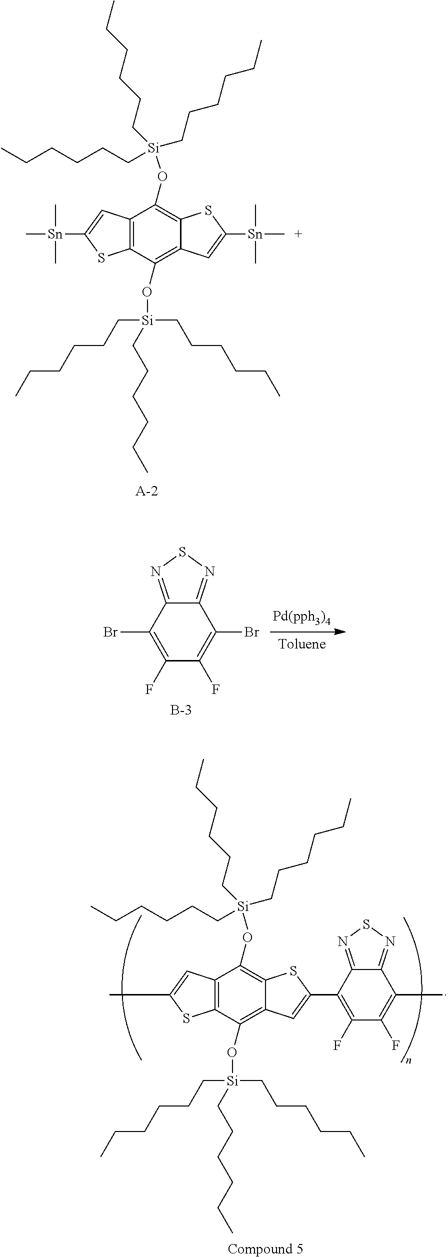

5 mL of toluene, Compound A-2 (0.3 mmol), Compound B-3 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.156 g of Compound 5 (yield: 55%).

### Preparation Example 8. Preparation of Compound 6

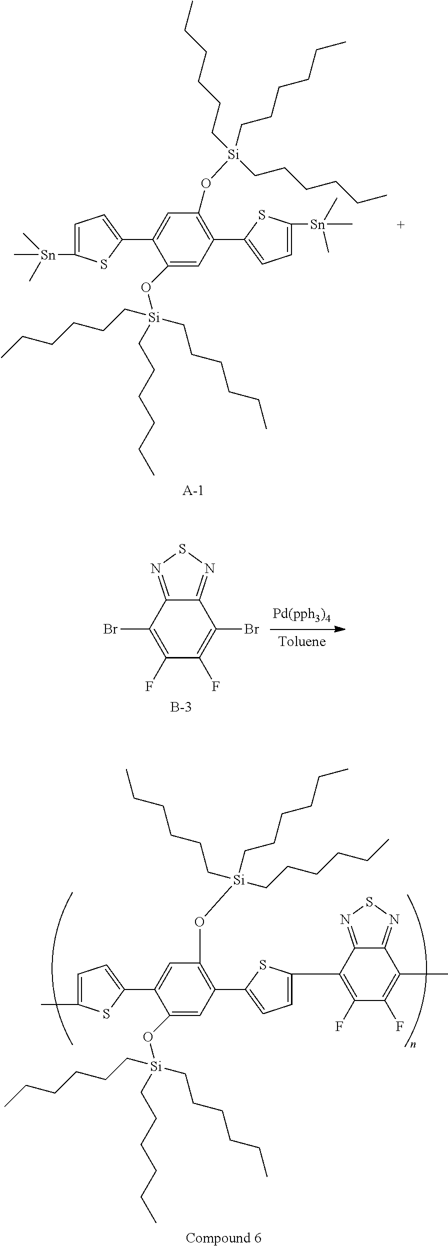

5 mL of toluene, Compound A-1 (0.3 mmol), Compound B-3 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.17 g of Compound 6 (yield: 56%).

### Preparation Example 9. Preparation of Compound 7

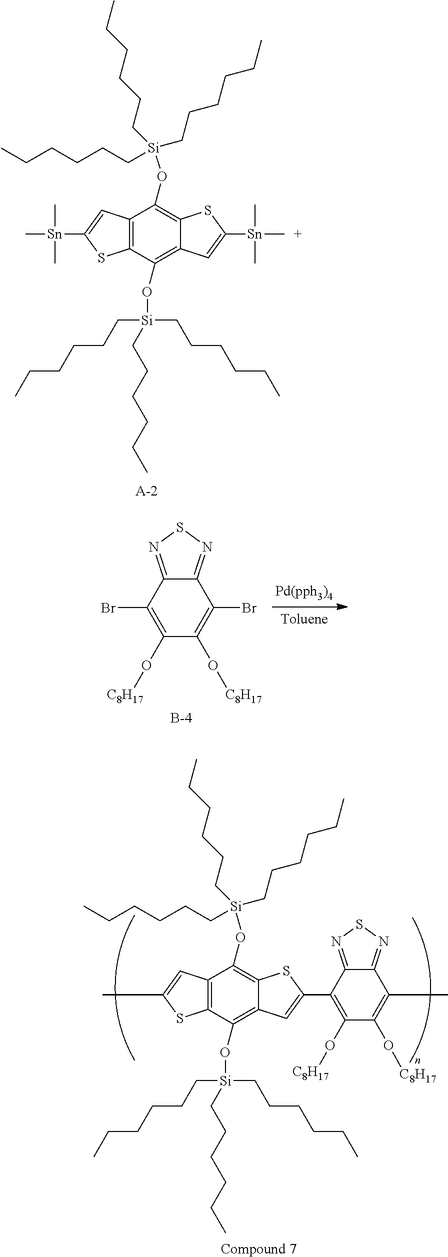

5 mL of toluene, Compound A-2 (0.3 mmol), Compound B-4 (0.3 mmol), and a tetrakis(triphenylphosphine)palladium(0) catalyst (Pd(PPh₃)₄) (0.06 mmol) were added to a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.22 g of Compound 7 (yield: 63%).

### Preparation Example 10. Preparation of Compound 8

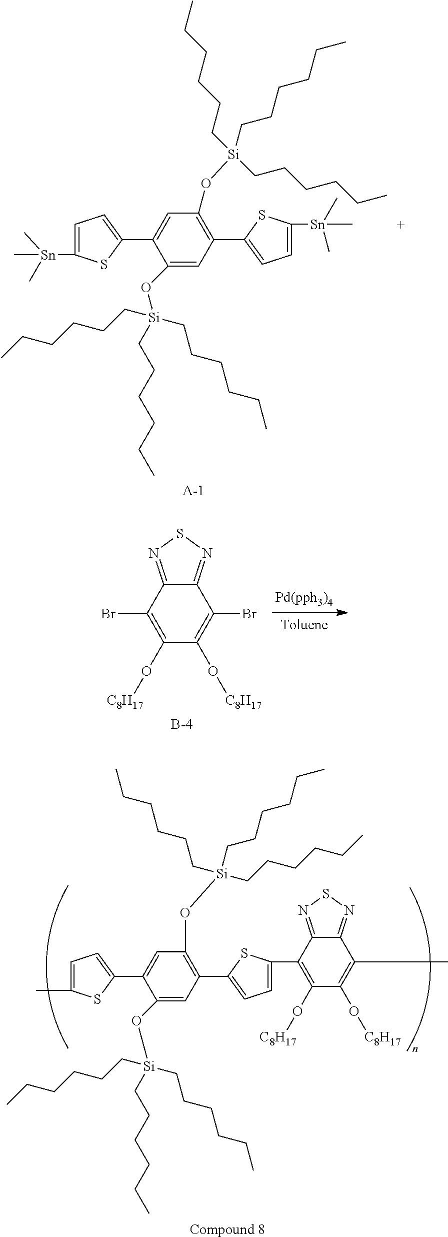

5 mL of toluene, Compound A-1 (0.3 mmol), Compound B-4 (0.3 mmol), and a tetrakis(triphenylphosphine)palladium(0) catalyst (Pd(PPh₃)₄) (0.06 mmol) were added to a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.23 g of Compound 8 (yield: 62%).

### Preparation Example 11. Preparation of Compound 9

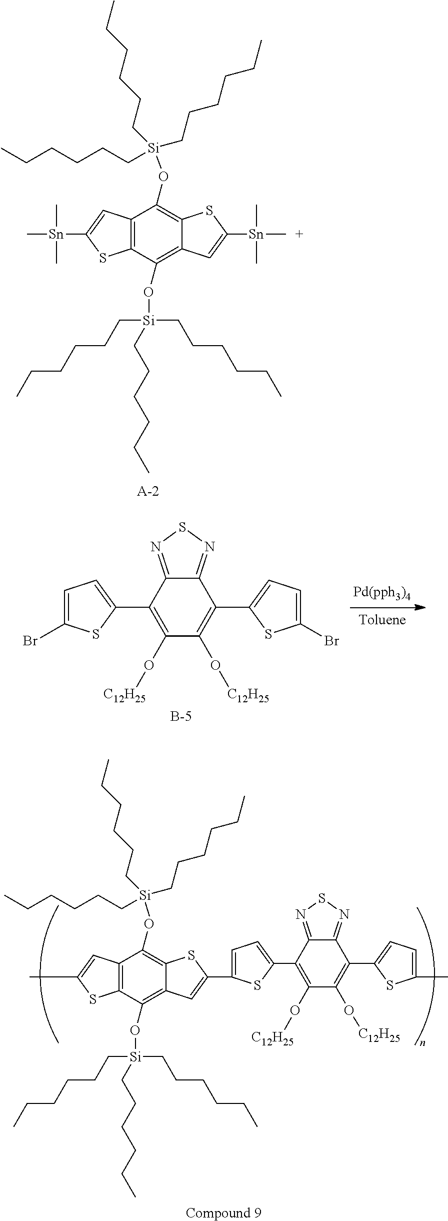

5 mL of toluene, Compound A-2 (0.3 mmol), Compound B-5 (0.3 mmol), and a tetrakis(triphenylphosphine)palladium(0) catalyst (Pd(PPh₃)₄) (0.06 mmol) were added to a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.35 g of Compound 9 (yield: 81%).

### Preparation Example 12. Preparation of Compound 10

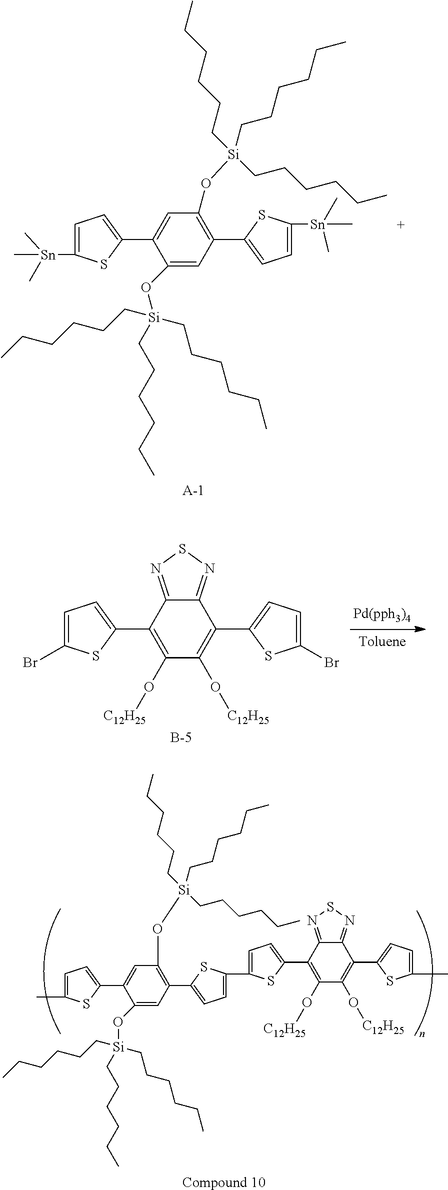

5 mL of toluene, Compound A-1 (0.3 mmol), Compound B-5 (0.3 mmol), and a tetrakis(triphenylphosphine)palladium(0) catalyst (Pd(PPh₃)₄) (0.06 mmol) were put into a 10-mL microwave tube, the microwave tube was sealed, and then the gas was removed therefrom for 10 minutes. Thereafter, the mixture was put into a reactor, and was allowed to react at each of 110° C., 130° C., and 140° C. for 10 minutes, and at 150° C. for 1 hour by gradually heating the mixture. Thereafter, 0.5 mL of Br-benzotrifluoride was added thereto, and the resulting mixture was stirred at 150° C. for 1 hour, and then cooled to room temperature. After the mixture was poured into 50 mL of methanol, the solid was filtered, the resulting mixture was subjected to soxhlet extraction in methanol, acetone, hexane, and chloroform, and then the solid was filtered by precipitating the extract in methanol again. Thereafter, the resulting material was dried under a vacuum condition to obtain 0.28 g of Compound 10 (yield: 61.8%)

### Example 1. Manufacture of Organic Solar Cell

A composite solution was prepared by dissolving Compound 1 prepared in the Preparation Example as a donor and PCBM as an acceptor at a ratio of 1:2 in chlorobenzene (CB). In this case, the concentration thereof was adjusted to 2.0 wt %, and the organic solar cell was made to have a structure of ITO/ZnO/a photoactive layer/MoO₃/Ag. A glass substrate coated with ITO was ultrasonically washed using distilled water, acetone, and 2-propanol, and the ITO surface was treated with ozone for 10 minutes, followed by a heat treatment at 120° C. for 10 minutes by spin-coating a ZnO precursor solution. Thereafter, the composite solution was filtered with a 0.45 m PP syringe filter, and then spin-coated to form a photoactive layer. Thereafter, MoO₃ was deposited onto the photoactive layer to a thickness of 5 nm to 20 nm at a rate of 0.4 Å/s in a thermal evaporator, thereby preparing a hole transport layer. Thereafter, Ag was deposited onto the hole transport layer to a thickness of 10 nm at a rate of 1 Å/s in the thermal evaporator, thereby manufacturing an organic solar cell.

### Example 2. Manufacture of Organic Solar Cell

An organic solar cell was manufactured in the same manner as in Example 1, except that Compound 2 was used instead of Compound 1 in Example 1.

### Example 3. Manufacture of Organic Solar Cell

An organic solar cell was manufactured in the same manner as in Example 1, except that Compound 3 was used instead of Compound 1 in Example 1.

### Example 4. Manufacture of Organic Solar Cell

An organic solar cell was manufactured in the same manner as in Example 1, except that Compound 4 was used instead of Compound 1 in Example 1.

### Example 5. Manufacture of Organic Solar Cell

An organic solar cell was manufactured in the same manner as in Example 1, except that Compound 5 was used instead of Compound 1 in Example 1.

### Example 6. Manufacture of Organic Solar Cell

An organic solar cell was manufactured in the same manner as in Example 1, except that Compound 6 was used instead of Compound 1 in Example 1.

### Example 7. Manufacture of Organic Solar Cell

An organic solar cell was manufactured in the same manner as in Example 1, except that Compound 7 was used instead of Compound 1 in Example 1.

### Example 8. Manufacture of Organic Solar Cell

An organic solar cell was manufactured in the same manner as in Example 1, except that Compound 8 was used instead of Compound 1 in Example 1.

### Example 9. Manufacture of Organic Solar Cell

An organic solar cell was manufactured in the same manner as in Example 1, except that Compound 9 was used instead of Compound 1 in Example 1.

### Example 10. Manufacture of Organic Solar Cell

An organic solar cell was manufactured in the same manner as in Example 1, except that Compound 10 was used instead of Compound 1 in Example 1.

The photoelectric conversion characteristics of the organic solar cells manufactured in Examples 1 to 10 were measured under the condition of 100 mW/cm² (AM 1.5), and the results are shown in the following Table 1.

TABLE 1

| | V_{oc} | J_{sc} | FF | η |
|---|---|---|---|---|
| | (V) | (mA/cm²) | (%) | (%) |
| Example 1 | 0.860 | 7.453 | 0.312 | 2.00 |
| Example 2 | 0.821 | 6.568 | 0.310 | 1.67 |
| Example 3 | 0.942 | 4.189 | 0.355 | 1.40 |
| Example 4 | 0.871 | 7.960 | 0.347 | 2.40 |
| Example 5 | 0.869 | 9.195 | 0.330 | 2.64 |
| Example 6 | 0.656 | 12.28 | 0.53 | 4.30 |
| Example 7 | 0.663 | 11.97 | 0.47 | 3.76 |
| Example 8 | 0.648 | 9.81 | 0.60 | 3.83 |
| Example 9 | 0.645 | 11.38 | 0.55 | 4.07 |
| Example 10 | 0.655 | 11.21 | 0.53 | 3.86 |

In Table 1, V_{oc}, J_{sc}, FF, and η mean an open-circuit voltage, a short-circuit current, a fill factor, and energy conversion efficiency, respectively. The open-circuit voltage and the short-circuit current are an X axis intercept and a Y axis intercept, respectively, in the fourth quadrant of the voltage-current density curve, and as the two values are increased, the efficiency of the solar cell is preferably increased. In addition, the fill factor is a value obtained by dividing the area of a rectangle, which may be drawn within the curve, by the product of the short-circuit current and the open-circuit voltage. The energy conversion efficiency may be obtained when these three values are divided by the intensity of the irradiated light, and the higher value is preferred.

FIG. 8 illustrates a current density according to a voltage with respect to organic solar cells manufactured in exemplary embodiments of the present specification.

### EXPLANATION OF SYMBOLS

101: Substrate
102: First electrode
103: Hole transport layer
104: Photoactive layer
105: Second electrode

1. A compound of Formula 1: 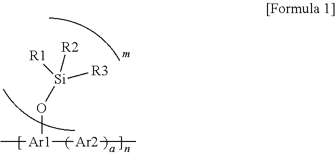
wherein:
Ar1 is a substituted or unsubstituted aryl group or a substituted or unsubstituted heterocyclic group;
Ar2 is a substituted or unsubstituted alkylene group, a substituted or unsubstituted cycloalkylene group, a substituted or unsubstituted arylene group, or a substituted or unsubstituted divalent heterocyclic group;
R1 to R3 are the same as or different from each other, and are each independently an alkyl group;
a is an integer from 1 to 5;
when a is 2 or more, multiple Ar2 are the same as or different from each other;
n is an integer from 1 to 10,000; and
m is 1 or 2.

2. The compound of claim 1, wherein the compound of Formula 1 is a compound of Formula 2: 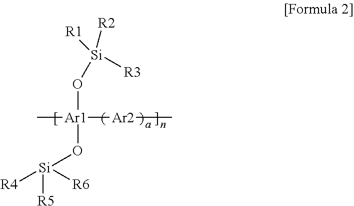
wherein Ar1, Ar2, a, and n are the same as those defined in Formula 1, and
R1 to R6 are the same as or different from each other, and are each independently an alkyl group.

3. The compound of claim 1, wherein Ar1 comprises any one or a combination of two or more among the following structures: 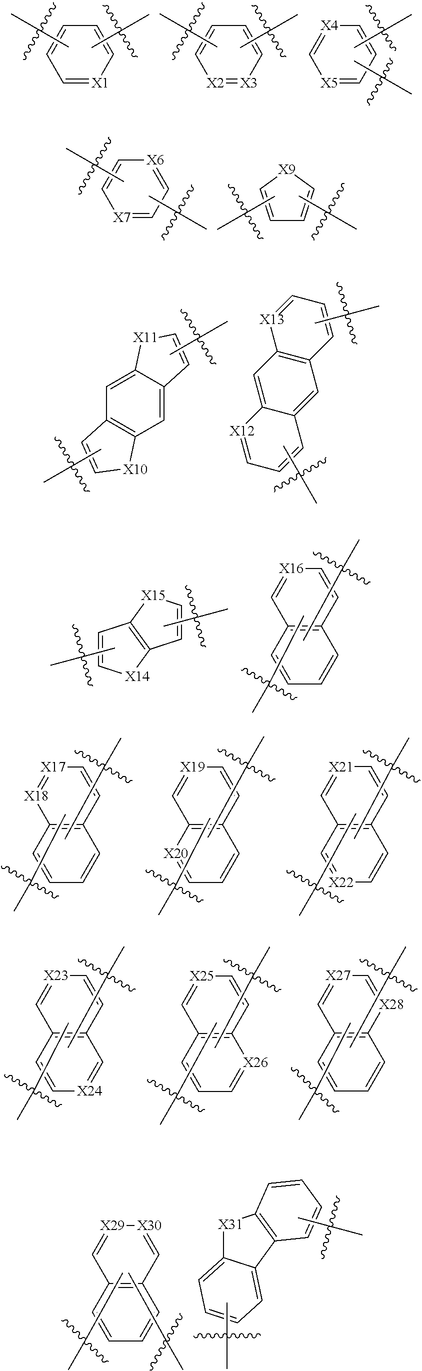 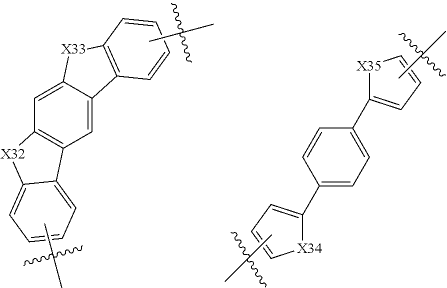
wherein:
X1 to X7, X12, X13, and X16 to X30 are the same as or different from each other, and are each independently N, CR, SiR, P, or GeR;
X9 to X11, X14, X15, and X31 to X35 are the same as or different from each other, and are each independently S, O, Se, Te, NR, CRR′, SiRR′, PR′, or GeRR′;
R and R′ are the same as or different from each other, and are each independently hydrogen, deuterium, a halogen group, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group a substituted or unsubstituted alkylsulfoxy group, a substituted or unsubstituted arylsulfoxy group, a substituted or unsubstituted alkenyl group a substituted or unsubstituted silyl group, a substituted or unsubstituted boron group, a substituted or unsubstituted amine group, a substituted or unsubstituted arylphosphine group, a substituted or unsubstituted phosphine oxide group a substituted or unsubstituted aryl group, or a substituted or unsubstituted heterocyclic group; and
one or two hydrogen atom(s) in the above structures is or are substituted with

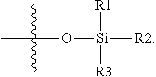

4. The compound of claim 1, wherein Ar2 comprises any one or a combination of two or more among the following structures: 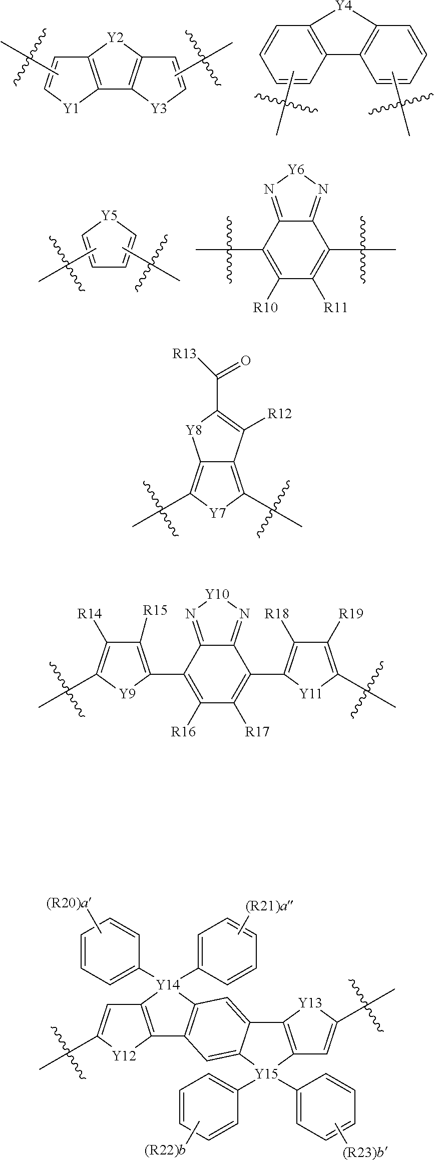
wherein:
a′, a″, b, and b′ are the same as or different from each other, and are each an integer from 0 to 5;
when a′, a″, b, and b′ are 2 or more, substituents in parenthesis are the same as or different from each other;
Y1 to Y13 are the same as or different from each other, and are each independently S, O, Se, Te, NR, CRR′, SiRR′, PR′, or GeRR′;
Y14 and Y15 are the same as or different from each other, and are each independently C, Si, or Ge; and
R10 to R23, R, and R′ are the same as or different from each other, and are each independently hydrogen, deuterium, a halogen group, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heterocyclic group.

5. The compound of claim 1, wherein the compound of Formula 1 is a compound of Formula 1-1: 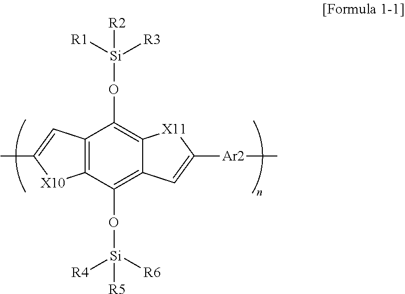
wherein:
Ar2, R1 to R3, and n are the same as those defined in Formula 1;
X10 and X11 are the same as or different from each other, and are each independently S, O, Se, Te, NR, CRR′, SiRR′, PR′, or GeRR′;
R4 to R6 are the same as or different from each other, and are each independently an alkyl group; and
R and R′ are the same as or different from each other, and are each independently hydrogen, deuterium, a halogen group, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heterocyclic group.

6. The compound of claim 1, wherein the compound of Formula 1 is a compound of any one of Formulae 1-11 to 1-16: 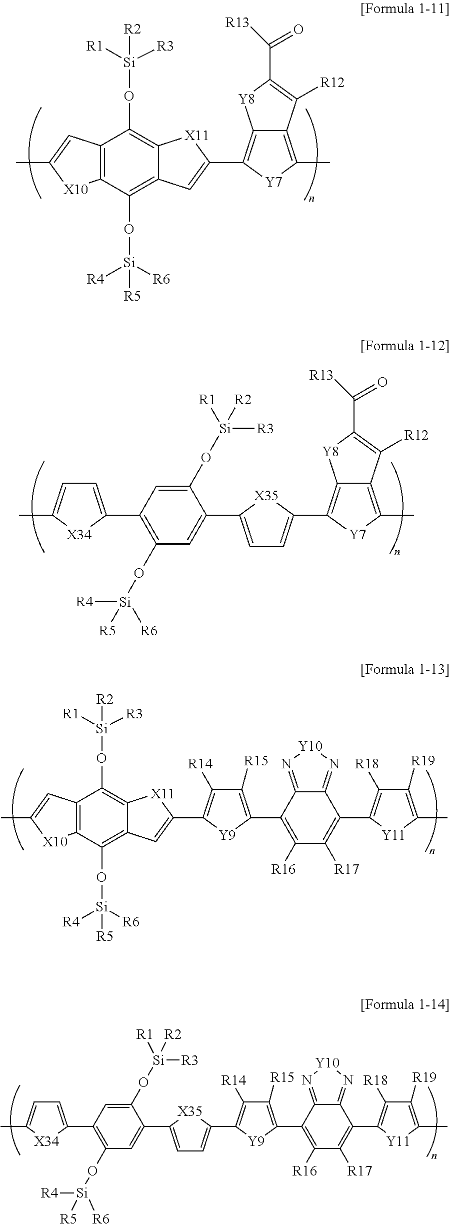 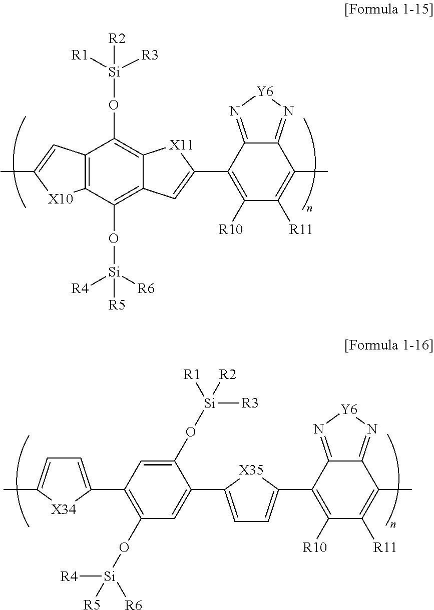
wherein:
R1 to R3 and n are the same as those defined in Formula 1;
X10, X11, X34, X35, and Y6 to Y11 are the same as or different from each other, and are each independently S, O, Se, Te, NR, CRR′, SiRR′, PR′, or GeRR′;
R4 to R6 are the same as or different from each other, and are each independently an alkyl group; and
R10 to R19, R, and R′ are the same as or different from each other, and are each independently hydrogen, deuterium, a halogen group, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heterocyclic group.

7. An organic solar cell comprising:
a first electrode;
a second electrode facing the first electrode; and
an organic material layer between the first electrode and the second electrode, the organic material layer comprising one or more layers that comprises a photoactive layer,
wherein the one or more layers of the organic material layer comprise the compound of claim 1.

8. The organic solar cell of claim 7, wherein the organic material layer comprises a hole transport layer, a hole injection layer, or a layer which simultaneously transports and injects holes, and
the hole transport layer, the hole injection layer, or the layer which simultaneously transports and injects holes comprises the compound.

9. The organic solar cell of claim 7, wherein the organic material layer comprises an electron injection layer, an electron transport layer or a layer which simultaneously injects and transports electrons, and
the electron injection layer, the electron transport layer or the layer which simultaneously injects and transports electrons comprises the compound.

10. The organic solar cell of claim 7, wherein the photoactive layer comprises an electron donor and an electron acceptor, and
the electron donor comprises the compound.

11. The organic solar cell of claim 7, wherein the organic solar cell further comprises one or two or more organic material layers selected from the group consisting of a hole injection layer, a hole transport layer, a hole blocking layer, a charge generation layer, an electron blocking layer, an electron injection layer, and an electron transport layer.

12. The compound of claim 5, wherein each of X10 and X11 is S.

13. The compound of claim 1, wherein the compound of Formula 1 is a compound of Formula 1-2: 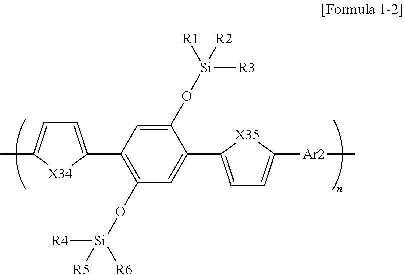
wherein:
Ar2, R1 to R3, and n are the same as those defined in Formula 1;
X34 and X35 are the same as or different from each other, and are each independently S, O, Se, Te, NR, CRR′, SiRR′, PR′, or GeRR′;
R4 to R6 are the same as or different from each other, and are each independently an alkyl group; and
R and R′ are the same as or different from each other, and are each independently hydrogen, deuterium, a halogen group, a nitrile group, a nitro group, a hydroxyl group, a carbonyl group, an ester group, an imide group, an amide group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted silyl group, a substituted or unsubstituted boron group, a substituted or unsubstituted amine group, a substituted or unsubstituted arylphosphine group, a substituted or unsubstituted phosphine oxide group, a substituted or unsubstituted aryl group, or a substituted or unsubstituted heterocyclic group.

14. The compound of claim 13, wherein each of X34 and X35 is S.

15. The compound of claim 6, wherein each of X10, X11, X34, and X35 is S.
